(19) United States
(12) Patent Application Publication
(10) Pub. No.: US 2015/0048052 A1
(43) Pub. Date: Feb. 19, 2015

(54) PLASMA PROCESSING APPARATUS

(71) Applicant: P2i LTD, Oxfordshire (GB)

(72) Inventors: Stephen Richard Coulson, Oxfordshire (GB); Fred Hopper, Oxfordshire (GB); Charles Edmund King, Oxfordshire (GB)

(21) Appl. No.: 14/240,301

(22) PCT Filed: Aug. 16, 2011
(86) PCT No.: PCT/GB2011/051546

§ 371 Date: Sep. 8, 2014

(51) Int. Cl. H01J 37/32

(52) U.S. Cl. CPC H01J 37/32137; H01J 37/32935; H01J 37/32541
USPC 216/71; 118/723 E; 156/345.48; 156/345.38; 427/569

(57) ABSTRACT

The present invention relates to an apparatus (10) for plasma processing an article (12), the apparatus comprising: a chamber (14) for receiving an article to be processed; electrode means (16) for generating an electric field in said chamber for establishing a plasma in said chamber so that said article can be processed; generation means (24) for generating alternating electrical energy for transmission to said electrode means (18); connection means for connecting said generation means to said electrode means (20); and control means for varying the location of nodes and anti-nodes of standing waves generated in said chamber during processing, so that a plurality of standing waves are generated over time which are not coincident with one another.

### FIELD OF THE INVENTION

This invention relates to an apparatus for plasma processing an article.

### BACKGROUND OF THE INVENTION

Plasma processing of articles is known hereto. Processing may include functionalizing, modifying or coating a surface of an article. Generally, a species (a vapour or gas) is introduced to a processing chamber and energised to form a plasma. In one known apparatus, a pair of electrodes is disposed inside the processing chamber and connected to a source of alternating electrical energy, such as an RF generator. If the processing chamber is sufficiently large, standing waves may be generated resulting in nodes and anti-nodes in the chamber. Species may be more efficiently energised at an anti-node and less efficiently energised at a node.

Accordingly, processing of articles in the chamber may not be homogenous since a surface of the article at an anti-node may be more effectively processed whilst a surface of an article at a node may be less effectively processed. Such a result is problematic since it is desirable to process the surface of an article homogenously so that the surface exhibits generally similar functionality after processing.

The problem of non-homogenous processing can to a certain extent be mitigated by processing an article for a longer duration so that the surface of an article coincident with a node may be adequately processed. However, such a solution is not generally satisfactory since it will inevitably result in excessive processing of a surface coincident with an anti-node, which wastes resources and time. Furthermore, the solution exacerbates the problem since processing for a longer duration results in less homogeneity.

The generation of standing waves in chambers would normally only be expected where the chamber size is sufficiently large to accommodate full, half or quarter waves. For instance, if the frequency of the applied electric energy is around 13.56 MHz then its wavelength is in the region of 20 m. However, it has been found that plasmas alter the dielectric properties of free space and can exhibit effective permittivities or dielectric constants in the region of 4 to 5. Under these circumstances a 13.56 MHz frequency can generate standing waves in processing chambers. Many commercial processing chambers have dimensions from 0.5 to 4 metres and so standing waves are possible because plasma permittivity reduces the effective wavelength.

### SUMMARY OF THE INVENTION

According to the present invention there is provided an apparatus for plasma processing an article, the apparatus comprising: a chamber for receiving an article to be processed; electrode means for generating an electric field in said chamber for establishing a plasma in said chamber so that said article can be processed; generation means for generating alternating electrical energy for transmission to said electrode means; connection means for connecting said generation means to said electrode means; and control means for varying the location of nodes and anti-nodes of standing waves generated in said chamber during processing, so that a plurality of standing waves are generated over time which are not coincident with one another.

Ideally the control means for varying the location of nodes and anti-nodes of standing waves generated in the chamber are arranged to control said connection means so that alternating electrical energy is transmitted to more than one region of the electrode means in sequence one region to another region during processing and/or by controlling the generation means so that the phase of the alternating electrical energy which is transmitted to the electrode means is varied during processing of an article such that said article can be processed generally homogenously.

In an embodiment, said electrode means comprises at least one electrode which is made from a material whose shape can be adapted in response to control by said control means.

In an embodiment, said electrode means and said connection means can connect said generation means to any one of a plurality of regions of at least one electrode.

In an embodiment, said control means controls the connection means to vary the electrical power that is transmitted to each of said regions of at least one electrode during processing.

In an embodiment, said electrode means comprises a plurality of electrodes arranged to apply different electric fields one with respect to another and wherein said connection means can connect said generation means to any one of said electrodes.

In an embodiment, said control means controls the connection means to vary the electrical power that is transmitted to each of said electrodes during processing.

In an embodiment, said connection means can connect said generation means to any one of a plurality of regions of at least one electrode of any of said electrodes.

In an embodiment, said control means controls the connection means to vary the electrical power that is transmitted to each of said regions of at least one electrode during processing.

In an embodiment, said control means controls said generation means and said connection means so that a relative RF phase of said alternating electrical energy is shifted between electrodes of the electrode means.

In an embodiment, said control means controls said connection means so that alternating electrical energy is switched between injection points on electrodes or between electrodes of the electrode means.

In an embodiment, said connection means comprises matching means for matching an impedance of said electrode means with an impedance of said generation means.

In an embodiment, said generation means is for generating RF electrical energy.

In an embodiment, said generation means generates electrical energy in the range from 13 MHz to 0.9 GHz.

In an embodiment, said generation means is for transmitting pulsed electrical energy.

The present invention also provides an apparatus for plasma processing an article, the apparatus comprising: a chamber for receiving an article to be processed; electrode means for generating an electric field in said chamber for establishing a plasma in said chamber so that said article can be processed; generation means for generating alternating electrical energy for transmission to said electrode means, wherein said electrode means and said generation means are configured to generate a plurality of standing wave patterns in said chamber; and control means for controlling said electrode means and said generation means so that a plurality of standing wave patterns are generated in said chamber during processing of an article.

In an embodiment, the apparatus comprises connection means which connect the generation means to the electrode means so that said alternating electric energy can be transmitted to at least two regions of the electrode means, each different configuration being a source of a standing wave pattern during processing, and wherein said control means controls the connection means so that a plurality of standing wave patterns are generated from respective said configurations when an article is processed.

In an embodiment, said electrode means has a plurality of conditions for generating a respective plurality of standing wave patterns when said electrode means is transmitted energy from said generation means, and said control means controls the condition of said electrode means so that a plurality of standing wave patterns are generated when an article is processed.

In an embodiment, said control means controls said generation means to vary a phase of the alternating electrical energy transmitted to said electrode means.

The present invention also provides a method for plasma processing an article using the apparatus described above, which comprises varying the location of nodes and anti-nodes of standing waves generated in a plasma processing chamber during processing, so that a plurality of standing waves are generated over time which are not coincident with one another.

Other preferred and/or optional features of the invention are defined in the accompanying claims.

Throughout the description and claims of this specification, the words “comprise” and “contain” and variations of the words, for example “comprising” and “comprises”, mean “including but not limited to”, and do not exclude other moieties, additives, components, integers or steps. Moreover the singular encompasses the plural unless the context otherwise requires: in particular, where the indefinite article is used, the specification is to be understood as contemplating plurality as well as singularity, unless the context requires otherwise.

Optional features of each aspect of the invention may be as described in connection with any of the other aspects. Other features of the invention will become apparent from the following examples. Generally speaking the invention extends to any novel one, or any novel combination, of the features disclosed in this specification (including any accompanying claims and drawings). Thus features, integers, characteristics, compounds, chemical moieties or groups described in conjunction with a particular aspect, embodiment or example of the invention are to be understood to be applicable to any other aspect, embodiment or example described herein unless incompatible therewith. Moreover unless stated otherwise, any feature disclosed herein may be replaced by an alternative feature serving the same or a similar purpose.

The invention will now be described, by the way of example only, with reference to the accompanying drawings, in which:

### BRIEF DESCRIPTION OF THE DRAWINGS

FIG. 1 shows a plasma processing apparatus;

FIG. 2 shows another plasma processing apparatus; and

FIG. 3 shows an alternative arrangement of an electrode means for the apparatus show in FIGS. 1 and/or 2.

### DETAILED DESCRIPTION OF THE ILLUSTRATED EMBODIMENTS

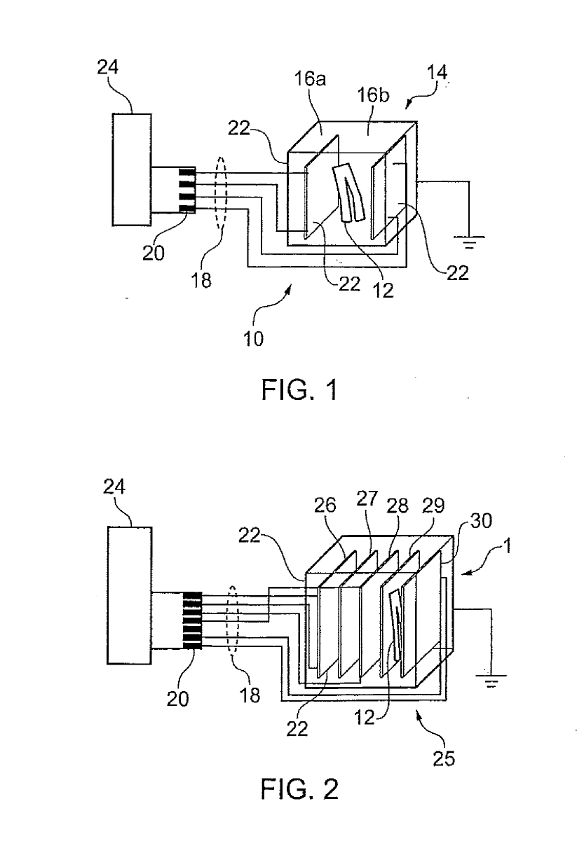

Referring to FIG. 1, apparatus 10 is shown for plasma processing an article, or articles, 12. The apparatus comprises a chamber 14 for receiving the article to be processed. Electrode means 16 (electrodes 16a, 16b) is provided for generating an electric field in the chamber 14 for establishing a plasma in the chamber so that the article can be processed. Generation means 24 generates alternating electrical energy for transmission to the electrode means 16. The generation means may be an RF generator which can be connected to a source of electrical energy, such as a mains supply, when the apparatus is in use.

Connection means 18 connects the generation means 24 to the electrode means 16. In one embodiment of the invention as shown in FIG. 1, the connection means is capable of connecting the generation means to any one of the plurality of regions 22 of the electrode means 16 so that alternating electrical energy can be injected into the chamber at a plurality of injection sites in sequence, one after another.

Control means 20 controls the connection means 18 so that the region 22 of the electrode means which is transmitted electrical energy varies during processing of an article such that the article 12 can be processed generally homogenously. In this way the nodes and anti-nodes of standing waves generated in the processing chamber are not fixed in location but instead the position of the standing waves in the chamber vary according to the site at which electrical energy is injected into the chamber. For instance, the nodes and anti-nodes of a standing wave generated at a given frequency when alternating energy is injected at a first injection site have different locations from the nodes and anti-nodes of a standing wave generated at that frequency when alternating energy is injected at a second injection site.

In prior art arrangements, electrical energy is transmitted at a fixed region of an electrode and therefore such arrangements have a propensity to generate standing waves comprising nodes and anti-nodes at fixed locations in the chamber 14. Therefore, processing of articles is not homogenous.

In another embodiment of the invention, the control means 20 causes the phase of alternating electrical energy injected into the chamber at any one injection to vary so that the position of the nodes and anti-nodes of standing waves generated are not fixed in location. For instance, during a first pulse of injected alternating electrical energy, the wave form generated is 90 degrees out of phase with the wave form generated during a second pulse of injected alternating electrical energy. Preferably, if only two phase shifts are adopted for consecutive pulses, the phase difference should not be 180 degrees as the nodes and anti-nodes would be co-incident. A phase modulator may be used to achieve phase modulation during an energy pulse or between successive energy pulses.

In the FIG. 1 apparatus, electrical energy is transmitted at a plurality of regions, or injections sites, of the electrode means 16. During processing of an article 12, energy may be transmitted first at one region and then subsequently at another region. The connection means may be configured such that two regions are established or may be configured such that more than two regions are established. The nodes and anti-nodes of a standing wave generated by injection of, for instance, an RF signal at any one region 22 are not coincident with the nodes and anti-nodes of a standing wave generated by injection of an RF signal at another region 22. In this way, the processing of articles is generally more homogenous than is the case with the prior art since, as can be seen from FIG. 1 any given point on the surface of an article is not positioned solely at a node or anti-node of each of the standing waves generated.

Accordingly, the electrode means 16 and the generation means 24 are configured to generate a plurality of standing wave patterns in said chamber. Therefore, the effect of one standing wave pattern is to diminish the effect of a second or further standing wave pattern. The control means 20 controls said electrode means and said generation means (in FIG. 1 by controlling the connection means 18) so that a plurality of standing wave patterns are generated in said chamber during processing of an article. Normally, one standing wave pattern is generated after another standing wave pattern.

It should be noted that whilst reference is made herein to nodes and anti-nodes, the energy supplied varies from a minimum at a node to a maximum at an anti-node and all values therebetween.

As shown in FIG. 1, the electrode means comprises a pair of electrodes 16a, 16b, each of generally planner rectangular form located at opposing lateral positions of the chamber 14. The electrodes 16a, 16b can be positioned in other arrangements, such as at upper and lower portions of the chamber. In addition a combination pair of electrodes positioned at 90 degrees to each other would be a suitable arrangement. Further, more than two electrodes may be adopted, particular if the chamber 14 is relatively large. The electrodes may be positioned outside the chamber if the chamber is made from a dielectric.

One electrode 16a is connected to connection means 18 for receiving electrical energy from generation means 24. The other electrode 16b is connected to earth. In an alternative arrangement, electrode 16b may be constituted by a wall of chamber 14, which is itself connected to earth.

A first region 22 is located at a lower region of electrode 16a and a second region 22 is located at an upper region of electrode 16a. When supplied with energy from the generation means 24 standing waves may propagate from the electrodes with differing spatial alignment. Whilst two regions 22 of electrode 16a are shown in FIG. 1, more than two regions 22 of an electrode can be selectively connected by the connection means to the generation means, according to operational requirements.

The connection means 18 connects the transmission means 24 to any one of plurality of regions of at least one electrode of said pair of electrodes. The connection means may comprise a switch and electrical conductors for connecting the switch to regions 22 of electrode 16a. In order to supply electrical power efficiently, the connection means may comprise matching means for matching an impedance of said electrode means with an impedance of said generation means. The matching means may comprise an LC matching circuit.

The generation means 24 in FIG. 1 is selected to transmit alternating electrical energy to the electrode 16a. An RF generator which can be connected to a power supply is suitable for this purpose. The generator may be configured to transmit at 13.56 MHz. The transmission may be pulsed, for instance, energy may be transmitted for a short duration which is sufficient to establish a plasma in the chamber followed by a pause of longer duration during which no energy is transmitted.

The control means 20 controls the connection means 18 to vary the electrical power that is transmitted to each of the regions 22 of electrode 16a during processing. The control means may comprise a programmable logic controller for controlling the transmission of energy to each of the regions 22. The PLC controls a region which is supplied with electrical energy and duration of such supply. RF energy is transmitted to different injection positions on electrode 16a by an RF switch or by switching in to the generation means a phase shifting element.

Additionally, or alternatively, the generation means 24 may comprise a phase modulator for modulating, or varying, the phase of alternating electrical energy supplied to the electrodes 16a, 16b.

Referring to FIG. 2, an apparatus 25 is shown for processing an article. Features of apparatus 25 which are equivalent to features shown in FIG. 1 are designated with the same reference numerals. In FIG. 2, the electrode means comprises a plurality of electrodes 26, 27, 28, 29 and 30. The electrodes are generally planar and rectangular. Three electrodes 26, 28 and 30 are driven with RF power and two electrodes 27 and 29 together with the chamber body 14 are earthed. Electrodes 26 and 30 are positioned in similar fashion to electrodes 16a, 16b shown in FIG. 1.

Additional electrodes 27, 28 and 29 are disposed generally parallel to the first pair of electrodes. The generation means 24 are arranged to apply RF power to the driven electrodes at different injection points and the control means and the connection means can change the points of injection or change the phase between injection points. In this way, the standing waves which may be generated by electrodes are dissimilar and therefore the corresponding nodes and anti-nodes are not coincident.

Connections means 18 is configured to connect selectively the generation means 24 to each of the driven electrodes. The control means 20 controls the connection means to vary the electrical power that is transmitted to each of said electrodes during processing.

In an alternative arrangement to FIG. 2, the connection means 18 can connect the generation means 24 to any one of a plurality of regions 22 of electrode 26, 28 and 30. In this case, the number of possible sources of standing waves can be increased thereby increasing homogeneity of article processing.

In such an alternative arrangement, the control means 20 controls the connection means 18 to vary the electrical power that is transmitted to each of said regions 22 of the electrode 26, 28 and 30 during processing.

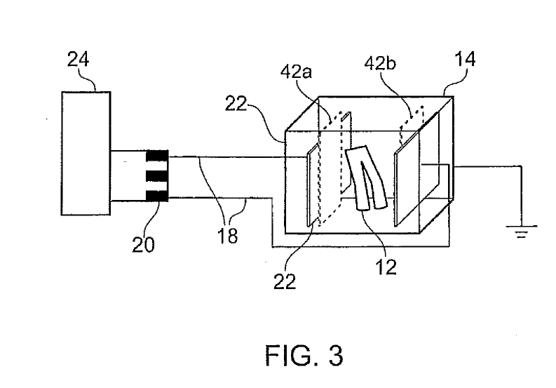

FIG. 3 shows electrode means 42a and 42b of a further apparatus for plasma processing an article. The other features of the apparatus are similar to those described with reference to FIGS. 1 and 2 and for brevity will not be described again here.

Each electrode 42a, 42b is made from a material whose shape can be adapted in response to control by control means 20. For instance, the electrodes may be made from a shape memory alloy or an expanding bellows strip which is responsive to a control signal in order to change from a first configuration shown in solid lines to a second configuration shown in broken lines. A standing wave propagates over the electrode in a dissimilar manner according to whether the electrode is in the first configuration or the second configuration. Accordingly, the control means can control the electrodes so that a plurality of standing wave patterns are generated in the chamber 14 during processing.

The invention has been described by way of several embodiments, with modifications and alternatives, but having read and understood this description further embodiments and modifications will be apparent to those skilled in the art. All such embodiments and modifications are intended to fall within the scope of the present invention as defined in the accompanying claims.

What is claimed is:

1. An apparatus for plasma processing an article, the apparatus comprising:
a chamber for receiving an article to be processed;
an electrode means for generating an electric field in said chamber for establishing a plasma in said chamber so that said article can be processed;
a generation means for generating alternating electrical energy for transmission to said electrode means;
a connection means for connecting said generation means to said electrode means; and
a control means for varying the location of nodes and anti-nodes of standing waves generated in said chamber during processing, so that a plurality of standing waves are generated over time which are not coincident with one another.

2. The apparatus as claimed in claim 1, wherein said control means controls the connection means so that alternating electrical energy is transmitted to more than one region of the electrode means in sequence, one region to another region, during processing of the article.

3. The apparatus as claimed in claim 1, wherein said control means varies the phase of the alternating electrical energy which is transmitted to the electrode means during processing of the article.

4. The apparatus as claimed in claim 1, wherein said electrode means comprises at least one electrode which is made from a material whose shape can be adapted in response to control by said control means.

5. The apparatus as claimed in claim 1, wherein said electrode means and said connection means can connect said generation means to any one of a plurality of regions of at least one electrode.

6. The apparatus as claimed in claim 5, wherein said control means controls the connection means to vary the electrical power that is transmitted to each of said regions of at least one electrode during processing.

7. The apparatus as claimed in claim 1, wherein said electrode means comprises a plurality of electrodes arranged to apply different electric fields one with respect to another and wherein said connection means can connect said generation means to any one of said plurality of electrodes.

8. The apparatus as claimed in claim 7, wherein said control means controls the connection means to vary the electrical power that is transmitted to each of said electrodes during processing.

9. The apparatus as claimed in claim 7, wherein said connection means can connect said generation means to any one of a plurality of regions of at least one electrode of any of said plurality of electrodes.

10. The apparatus as claimed in claim 9, wherein said control means controls the connection means to vary the electrical power that is transmitted to each of said regions of at least one electrode during processing.

11. The apparatus as claimed in claim 1, wherein said control means controls said generation means and said connection means so that a relative RF phase of said alternating electrical energy is shifted between electrodes of the electrode means.

12. The apparatus as claimed in claim 1, wherein said control means controls said connection means so that alternating electrical energy is switched between injection points on electrodes or between electrodes of the electrode means.

13. The apparatus as claimed in claim 1, wherein said connection means comprises matching means for matching an impedance of said electrode means with an impedance of said generation means.

14. The apparatus as claimed in claim 1, wherein said generation means is for generating RF electrical energy.

15. The apparatus as claimed in claim 1, wherein said generation means generates electrical energy in the range from 13 MHz to 0.9 GHz.

16. The apparatus as claimed in claim 1, wherein said generation means is for transmitting pulsed electrical energy.

17. A method for plasma processing an article using an apparatus according to claim 1, which comprises varying a location of nodes and anti-nodes of standing waves generated in a plasma processing chamber during processing, so that a plurality of standing waves are generated over time which are not coincident with one another.

18. The apparatus as claimed in claim 4, wherein said electrode means comprises a plurality of electrodes arranged to apply different electric fields one with respect to another and wherein said connection means can connect said generation means to any one of said electrodes.

19. The apparatus as claimed in claim 18, wherein said control means controls the connection means to vary the electrical power that is transmitted to each of said plurality of electrodes during processing.

20. The apparatus as claimed in claim 18, wherein said connection means can connect said generation means to any one of a plurality of regions of at least one electrode of any of said plurality of electrodes.
